(19) United States
(12) Patent Application Publication
(10) Pub. No.: US 2024/0038896 A1
(43) Pub. Date: Feb. 1, 2024

(54) THIN FILM TRANSISTOR AND METHOD OF MANUFACTURING THE SAME

(71) Applicant: ADRC. CO. KR, Seoul (KR)

(72) Inventors: Jin JANG, Seoul (KR); Jun Hyuk Cheon, Seoul (KR); Da Hoon Jung, Guri-si (KR)

(21) Appl. No.: 18/108,114

(22) Filed: Feb. 10, 2023

(30) Foreign Application Priority Data
Jul. 28, 2022 (KR) 10-2022-0094164

(51) Int. Cl. H01L 29/786; H01L 29/08; H01L 29/66

(52) U.S. Cl. CPC H01L 29/7869; H01L 29/0847; H01L 29/66969; H01L 29/045

(57) ABSTRACT

Disclosed is a thin film transistor including: a gate electrode disposed on a substrate; a semiconductor layer overlapping the gate electrode with a gate insulating film interposed therebetween, and a source region and a drain region which are in contact with the semiconductor layer, in which the semiconductor layer includes a crystallized oxide semiconductor, and the crystallized oxide semiconductor includes a crystal having an X-ray diffraction (XRD) main peak Miller index (hkl) value of (009).

### CROSS-REFERENCE TO RELATED APPLICATION

This application claims priority to and the benefit of Korean Patent Application No. 10-2022-0094164 filed in the Korean Intellectual Property Office on Jul. 28, 2022, the entire contents of which are incorporated herein by reference.

### BACKGROUND

### 1. Field

The present disclosure relates to a transistor and a method of manufacturing the same.

### 2. Description of the Related Art

A thin film transistor constitutes a switching element by using three terminals: a gate electrode to which a control signal is applied, a source electrode to which a data voltage is applied, and a drain electrode outputting a data voltage. In addition, the thin film transistor includes an active layer overlapping the gate electrode as a channel layer, and the active layer includes a semiconductor.

On the other hand, as technologies of displays and the like including thin film transistors develop, the development of thin film transistors capable of high-speed driving is urgently needed. For this purpose, a technology using an oxide semiconductor with high electron mobility as an active layer has been developed, but a thin film transistor with improved performance is required to be used for high-speed driving.

In addition, as the manufacturing process of the thin film transistor with improved performance becomes more complicated, the manufacturing cost increases, so that there is a need to provide a thin film transistor capable of maintaining high performance while lowering the manufacturing cost by simplifying the manufacturing process, and a method of manufacturing the same.

The above information disclosed in this Background section is only for enhancement of understanding of the background of the described technology, and therefore it may contain information that does not form the prior art that is already known in this country to a person of ordinary skill in the art.

### SUMMARY

The described technology has been made in an effort to provide a thin film transistor capable of lowering manufacturing cost and maintaining high performance, and a method of manufacturing the same.

However, the object to be solved in the embodiments is not limited to the foregoing object, and may be variously extended in the scope of the technical spirit included in the embodiments.

An embodiment provides a thin film transistor including: a gate electrode disposed on a substrate; a semiconductor layer including a channel region overlapping the gate electrode with a gate insulating film interposed therebetween, and a source region and a drain region disposed on both sides of the channel region; and a source electrode and a drain electrode which are in contact with the source region and the drain region of the semiconductor layer, in which the semiconductor layer includes a crystallized oxide semiconductor, the crystallized oxide semiconductor includes a crystal having an X-ray diffraction (XRD) main peak Miller index (hkl) value of (009), and the source region and the drain region are doped with fluorine.

The source region may include a first offset region between a region overlapping the source electrode and the channel region, the drain region may include a second offset region between a region overlapping the drain electrode and the channel region, and the first offset region and the second offset region may be doped with fluorine.

The crystal of the crystallized oxide semiconductor may include a C Axis Aligned Crystal (CAAC).

The semiconductor layer may include indium.

The semiconductor layer may include at least one of Indium-Gallium-Zinc Oxide (IGZO), Indium-Zinc-Tin Oxide (IZTO), Indium-Gallium-Zinc-Tin Oxide (IGZTO), Indium-Gallium Oxide (IGO), and Indium-Gallium-Tin Oxide (IGTO).

The source region and the drain region may be plasma-treated with nitrogen trifluoride.

Sheet resistance of the source region and the drain region may be about 2 kohm/square (kΩ/sq.) or less.

Sheet resistance of the source region and the drain region may be about 1.3 kohm/square (kΩ/sq.) or less.

Sheet resistance of the source region and the drain region may be about 1 kohm/square (kΩ/sq.) or less.

The semiconductor layer may be formed at a process temperature of about 350 degrees (° C.) to about 450 degrees (° C.).

Another embodiment provides a method of manufacturing a thin film transistor, the method including: forming a gate electrode on a substrate; forming a semiconductor layer including a channel region overlapping the gate electrode with a gate insulating film interposed therebetween, and a source region and a drain region disposed on both sides of the channel region, plasma-treating the source region and the drain region of the semiconductor layer by using gas containing fluorine, and forming a source electrode and a drain electrode which are in contact with the semiconductor layer, in which the forming of the semiconductor layer includes spray coating a solution containing a volatile solvent, a metal precursor, and a stabilizer on the substrate.

The forming of the semiconductor layer may be performed at a process temperature of about 350 degrees (° C.) to about 450 degrees (° C.).

The forming of the semiconductor layer may be performed at a process temperature of about 400 degrees (° C.) to about 450 degrees (° C.).

The plasma treating may be plasma-treatment using nitrogen trifluoride.

The plasma-treating may include plasma-treating the semiconductor layer by using the gate electrode disposed on the channel region as a mask.

The spray coating may include: preparing the solution by mixing the metal precursor and the stabilizer with the volatile solvent; spraying the solution together with carrier gas onto the substrate, and evaporating the volatile solvent of the solution.

The forming of the semiconductor layer may include repeating the spray coating several times.

According to the thin film transistor and the method of manufacturing the same according to the embodiment, it is possible to lower the manufacturing cost and maintain high performance.

However, the effects of the embodiments are not limited to the above-described effects, and it is apparent that they can be variously expanded without departing from the spirit and scope of this disclosure.

### BRIEF DESCRIPTION OF THE DRAWINGS

FIG. 1 is a cross-sectional view of a thin film transistor according to an embodiment.

FIG. 2 is a cross-sectional view of a thin film transistor according to another embodiment.

FIGS. 3A to 3E are cross-sectional views illustrating a method of manufacturing a thin film transistor according to an embodiment.

FIGS. 4A to 4C are cross-sectional views illustrating a method of manufacturing a thin film transistor according to another embodiment.

FIGS. 5 and 6 are graphs illustrating the results of one experimental example.

FIG. 7 is a graph illustrating the results of one experimental example.

### DETAILED DESCRIPTION OF THE EMBODIMENTS

In the following detailed description, only certain embodiments have been shown and described, simply by way of illustration. However, this disclosure can be variously implemented and is not limited to the following embodiments.

Accordingly, the drawings and description are to be regarded as illustrative in nature and not restrictive. Like reference numerals designate like elements throughout the specification.

Further, the accompanying drawings are provided for helping to easily understand embodiments disclosed in the present specification, and the technical spirit disclosed in the present specification is not limited by the accompanying drawings, and it will be appreciated that this disclosure includes all of the modifications, equivalent matters, and substitutes included in the spirit and the technical scope of this disclosure.

In addition, the size and thickness of each configuration shown in the drawings are arbitrarily shown for understanding and ease of description, but this disclosure is not limited thereto. In the drawings, the thickness of layers, films, panels, regions, etc., are exaggerated for clarity. In the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Further, throughout the specification, when it is referred to as “connected”, this does not only mean that two or more constituent elements are directly connected, but may mean that two or more constituent elements are indirectly connected through another constituent element, are physically connected, electrically connected, or are integrated even though two or more constituent elements are referred as different names depending on a location and a function.

Hereinafter, various embodiments and modifications will be described in detail with reference to the drawings.

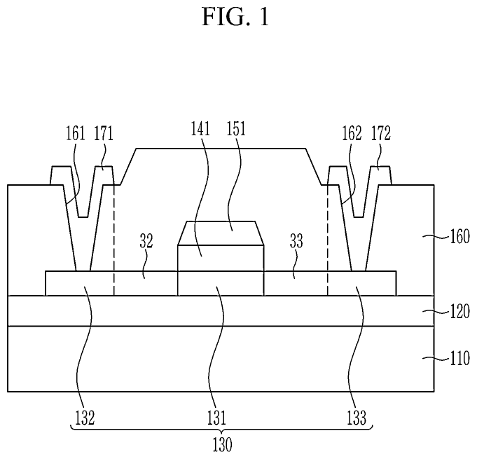

A thin film transistor according to an embodiment will be described with reference to FIG. 1. FIG. 1 is a cross-sectional view of a thin film transistor according to an embodiment.

Referring to FIG. 1, a buffer layer 120 is disposed on a substrate 110. The buffer layer 120 may have a single-layer or multi-layer structure. Although the buffer layer 120 is illustrated as a single layer in FIG. 1, the buffer layer 120 may be multilayered according to an embodiment. The buffer layer 120 may include an organic insulating material or an inorganic insulating material. For example, the buffer layer 120 may include at least one of silicon nitride (SiNx), silicon oxide (SiOx), and silicon nitric oxide (SiOxNy).

A semiconductor layer 130 including a first region 131, a second region 132, and a third region 133 is disposed on the buffer layer 120.

The semiconductor layer 130 may include an oxide semiconductor. The oxide semiconductor may include at least one of a primary metal oxide, such as indium (In) oxide, tin (Sn) oxide, or zinc (Zn) oxide, a binary metal oxide, such as In—Zn-based oxide, Sn—Zn-based oxide, Al—Zn-based oxide, Zn—Mg-based oxide, Sn—Mg-based oxide, In—Mg-based oxide, or In—Ga-based oxide, a ternary metal oxide, such as In—Ga—Zn-based oxide, In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, or In—Lu—Zn-based oxide, and a quaternary metal oxide, such as In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, or In—Hf—Al—Zn-based oxide. For example, the semiconductor layer 130 may include Indium-Gallium-Zinc Oxide (IGZO) among the In—Ga—Zn-based oxide.

The semiconductor layer 130 may include at least one of Indium-Gallium-Zinc Oxide (IGZO), Indium-Zinc-Tin Oxide (IZTO), Indium-Gallium-Zinc-Tin Oxide (IGZTO), Indium-Gallium Oxide (IGO), and Indium-Gallium-Tin Oxide (IGTO).

The first region 131 of the semiconductor layer 130 may be a channel region, and the second region 132 and the third region 133 of the semiconductor layer 130 may be a source region and a drain region.

The semiconductor layer 130 may be formed by a spray coating method, and may be crystallized without a separate annealing process. When the semiconductor layer 130 is formed by a spray coating method, the semiconductor layer 130 may be laminated under a process temperature of about 350 degrees (° C.) to about 450 degrees (° C.). More specifically, when the semiconductor layer 130 is formed by a spray coating method, the semiconductor layer 130 may be laminated under a process temperature of about 400 degrees (° C.) to about 450 degrees (° C.).

The crystal of the semiconductor layer 130 may include a C Axis Aligned Crystal (CAAC) having an X-ray diffraction (XRD) main peak Miller index (hkl) value corresponding to (009).

The second region 132 and the third region 133 of the semiconductor layer 130 may be subjected to fluorine plasma treatment. For example, the second region 132 and the third region 133 may be plasma-treated with nitrogen trifluoride.

The second region 132 and the third region 133, which are the source region and the drain region of the semiconductor layer 130, are doped through plasma processing, so that it is possible to increase the efficiency of the channel of the thin film transistor by reducing the resistance and increasing the carrier concentration.

Sheet resistance of the second region 132 and the third region 133 of the semiconductor layer 130 may be about 2 kohm/square (kΩ/sq.) or less, and for example, the sheet resistance of the second region 132 and the third region 133 of the semiconductor layer 130 may be about 1.3 kohm/square (kΩ/sq.) or less, and more specifically, the sheet resistance of the second region 132 and the third region 133 of the semiconductor layer 130 may be about 1 kohm/square (kΩ/sq.) or less.

A gate insulating film 141 is disposed on the first region 131 of the semiconductor layer 130. The gate insulating film 141 may include an organic insulating material or an inorganic insulating material, and for example, the gate insulating film 141 may include at least one of silicon nitride, silicon oxide, silicon oxynitride, or tetra ethyl ortho silicate (TEOS).

A gate electrode 151 is disposed on the gate insulating film 141. The gate electrode 151 is disposed to overlap the first region 131 of the semiconductor layer 130, and the gate insulating film 141 is interposed between the first region 131 of the semiconductor layer 130 and the gate electrode 151.

The gate electrode 151 may be a multilayer in which a metal film including any one of copper (Cu), a copper alloy, aluminum (Al), an aluminum alloy, molybdenum (Mo), and a molybdenum alloy is stacked.

A passivation layer 160 is disposed on the semiconductor layer 130, the gate insulating film 141, and the gate electrode 151. The passivation layer 160 may include at least one of silicon nitride, silicon oxide, silicon oxynitride, and tetra ethyl ortho silicate (TEOS), and may be made of an organic material, such as polyacrylates resin and polyimides resin, or a laminated film of an organic material and an inorganic material.

The passivation layer 160 includes a first contact hole 161 overlapping the second region 132 of the semiconductor layer 130 and a second contact hole 172 overlapping the third region 133 of the semiconductor layer 130.

A source electrode 171 and a drain electrode 172 are disposed on the passivation layer 160. The source electrode 171 is connected to the second region 132 that is the source region of the semiconductor layer 130 by the first contact hole 161 of the passivation layer 160, and the drain electrode 172 is connected to the third region 133 that is the drain region of the semiconductor layer 130 through the second contact hole 162 of the passivation layer 160.

The source electrode 171 and the drain electrode 172 may include an aluminum-based metal, a silver-based metal, and a copper-based metal having a low resistivity, and for example, may have a triple layer structure including a lower film including a refractory metal, such as titanium, molybdenum, chromium, and tantalum, or an alloy thereof, an interlayer film including aluminum-based metal, silver-based metal, or copper-based metal having low resistivity, and an upper layer including a refractory metal, such as titanium, molybdenum, chromium, and tantalum.

The gate electrode 151, the source electrode 171, and the drain electrode 172 described above form a thin film transistor (TFT) together with the semiconductor layer 130, and the channel of the thin film transistor is formed in the first region 131 between the second region 132 serving as the source region and the third region 133 serving as the drain region of the semiconductors 131, 132, and 133.

The second region 132 of the semiconductor layer 130 may include a first offset region 32 between the region overlapping the source electrode 171 and the first region 131 serving as the channel region, and the third region 133 of the semiconductor layer 130 may include a second offset region 33 between the region overlapping the drain electrode 172 and the first region 131 serving as the channel region. As described above, the second region 132 and the third region 133 that are the source region and the drain region of the semiconductor layer 130 may be subjected to fluorine plasma treatment, and for example, the second region 132 and the third region 133 may be plasma-treated with nitrogen trifluoride. Accordingly, the first offset region 32 and the second offset region 33 disposed on both sides of the channel region 131 may also be subjected to fluorine plasma treatment to be doped with fluorine.

Accordingly, the first offset region 32 and the second offset region 33 are also plasma-doped, for example, fluorine plasma-doped, thereby preventing an increase in resistance that may occur in the first offset region 32 and the second offset region 33 and increasing the efficiency of a channel of the thin film transistor.

According to the thin film transistor according to the present embodiment, the semiconductor layer 130 may include an oxide semiconductor, the semiconductor layer 130 may be formed by a spray coating method, and the semiconductor layer 130 may have a crystal having an axis of a C Axis Aligned Crystal (CAAC) having an X-ray diffraction (XRD) main peak Miller index (hkl) value corresponding to (009). The second region 132 and the third region 133 of the semiconductor layer 130 may be subjected to fluorine plasma treatment. For example, the second region 132 and the third region 133 may be plasma-treated with nitrogen trifluoride. Sheet resistance of the second region 132 and the third region 133 of the semiconductor layer 130 may be about 2 kohm/square (kΩ/sq.) or less, and for example, the sheet resistance of the second region 132 and the third region 133 of the semiconductor layer 130 may be about 1.3 kohm/square (kΩ/sq.) or less, and more specifically, the sheet resistance of the second region 132 and the third region 133 of the semiconductor layer 130 may be about 1 kohm/square (kΩ/sq.) or less.

When the oxide semiconductor layer constituting the semiconductor layer of the thin film transistor is crystallized, the performance of the thin film transistor may be higher than that of the thin film transistor including the non-crystallized oxide semiconductor layer. In general, in order to crystallize the oxide semiconductor layer, the oxide semiconductor layer may be crystallized by stacking the oxide semiconductor layer and annealing the stacked oxide semiconductor layer at a high temperature. However, when the oxide semiconductor layer is crystallized by high-temperature annealing, the crystallization of the surface to which high-temperature energy is applied is large, and the crystallization may decrease toward the opposite side, and crystallization may be non-uniform according to energy distribution. Also, by including an annealing process for separate crystallization, the manufacturing cost may be high.

However, as described above, the semiconductor layer of the thin film transistor according to the present embodiment may be formed by the spray coating method to have a crystal having an axis of C Axis Aligned Crystal (CAAC) having X-ray diffraction (XRD) main peak Miller index (hkl) value corresponding to (009) without a separate annealing process, and the manufacturing process is not complicated, so that the performance of the transistor may be improved without increasing the manufacturing cost. In addition, the second region 132 and the third region 133 of the semiconductor layer 130 may be treated with fluorine plasma, and the sheet resistance of the second region 132 and the third region 133 of the semiconductor layer 130 may be about 2 kohm/square (kΩ/sq.) or less, and for example, the sheet resistance of the second region 132 and the third region 133 of the semiconductor layer 130 may be about 1.3 kohm/square (kΩ/sq.) or less, and more specifically, the sheet resistance of the second region 132 and the third region 133 of the semiconductor layer 130 may be about 1 kohm/square (kΩ/sq.) or less, so that the efficiency of the channel of the thin film transistor may be increased by reducing the resistance of the source region and the drain region and increasing the carrier concentration.

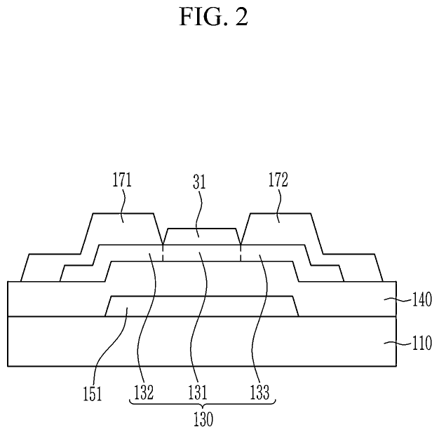

A thin film transistor according to an embodiment will be described with reference to FIG. 2. FIG. 2 is a cross-sectional view of a thin film transistor according to another embodiment.

Referring to FIG. 2, a gate electrode 151 may be disposed on a substrate 110, and a gate insulating film 141 may be disposed on the gate electrode 151.

The gate electrode 151 may be a multilayer in which a metal film including any one of copper (Cu), a copper alloy, aluminum (Al), an aluminum alloy, molybdenum (Mo), and a molybdenum alloy is stacked.

The gate insulating film 141 may include an organic insulating material or an inorganic insulating material, and for example, the gate insulating film 141 may include at least one of silicon nitride, silicon oxide, silicon oxynitride, or tetra ethyl ortho silicate (TEOS).

A semiconductor layer 130 including a first region 131, a second region 132, and a third region 133 is disposed on the gate insulating film 141.

The semiconductor layer 130 may include an oxide semiconductor. The oxide semiconductor may include at least one of a primary metal oxide, such as indium (In) oxide, tin (Sn) oxide, or zinc (Zn) oxide, a binary metal oxide, such as In—Zn-based oxide, Sn—Zn-based oxide, Al—Zn-based oxide, Zn—Mg-based oxide, Sn—Mg-based oxide, In—Mg-based oxide, or In—Ga-based oxide, a ternary metal oxide, such as In—Ga—Zn-based oxide, In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, or In—Lu—Zn-based oxide, and a quaternary metal oxide, such as In—Sn—Ga—Zn-based oxide, In—Hf—Ga—Zn-based oxide, In—Al—Ga—Zn-based oxide, In—Sn—Al—Zn-based oxide, or In—Sn—Hf—Zn-based oxide.

The semiconductor layer 130 may include at least one of Indium-Gallium-Zinc Oxide (IGZO), Indium-Zinc-Tin Oxide (IZTO), Indium-Gallium-Zinc-Tin Oxide (IGZTO), Indium-Gallium Oxide (IGO), and Indium-Gallium-Tin Oxide (IGTO).

The semiconductor layer 130 may be formed by a spray coating method, and may be crystallized without a separate annealing process. When the semiconductor layer 130 is formed by a spray coating method, the deposition temperature may be about 350° C. to about 450° C.

The crystal of the semiconductor layer 130 may include a C Axis Aligned Crystal (CAAC) having an X-ray diffraction (XRD) main peak (Miller index) (hkl) value corresponding to (009).

The second region 132 and the third region 133 of the semiconductor layer 130 may be subjected to fluorine plasma treatment. For example, the second region 132 and the third region 133 may be plasma-treated with nitrogen trifluoride.

The second region 132 and the third region 133, which are the source region and the drain region of the semiconductor layer 130, are doped through plasma processing, so that it is possible to increase the efficiency of the channel of the thin film transistor by reducing the resistance and increasing the carrier concentration.

Sheet resistance of the second region 132 and the third region 133 of the semiconductor layer 130 may be about 2 kohm/square (kΩ/sq.) or less, and for example, the sheet resistance of the second region 132 and the third region 133 of the semiconductor layer 130 may be about 1.3 kohm/square (kΩ/sq.) or less, and more specifically, the sheet resistance of the second region 132 and the third region 133 of the semiconductor layer 130 may be about 1 kohm/square (kΩ/sq.) or less.

A blocking layer 31 may be disposed on the first region 131, which is a channel region of the semiconductor layer 130. The blocking layer 31 may include an inorganic insulating layer.

A source electrode 171 is disposed on the second region 132 that is the source region of the semiconductor layer 130, and a drain electrode 172 is disposed on the third region 133 that is the drain region of the semiconductor layer 130.

The source electrode 171 and the drain electrode 172 may include an aluminum-based metal, a silver-based metal, and a copper-based metal having a low resistivity, and for example, may have a triple layer structure including a lower film including a refractory metal, such as titanium, molybdenum, chromium, and tantalum, or an alloy thereof, an interlayer film including aluminum-based metal, silver-based metal, or copper-based metal having low resistivity, and an upper layer including a refractory metal, such as titanium, molybdenum, chromium, and tantalum.

The gate electrode 151, the source electrode 171, and the drain electrode 172 described above form a thin film transistor (TFT) together with the semiconductor layer 130, and the channel of the thin film transistor is formed in the first region 131 between the second region 132 serving as the source region and the third region 133 serving as the drain region of the semiconductors 131, 132, and 133.

According to the thin film transistor according to the present embodiment, the semiconductor layer 130 may include an oxide semiconductor, the semiconductor layer 130 may be formed by a spray coating method, and the semiconductor layer 130 may have a crystal having an axis of a C Axis Aligned Crystal (CAAC) having an X-ray diffraction (XRD) main peak Miller index (hkl) value corresponding to (009). The second region 132 and the third region 133 of the semiconductor layer 130 may be subjected to fluorine plasma treatment. For example, the second region 132 and the third region 133 may be plasma-treated with nitrogen trifluoride. Sheet resistance of the second region 132 and the third region 133 of the semiconductor layer 130 may be about 2 kohm/square (kΩ/sq.) or less, and for example, the sheet resistance of the second region 132 and the third region 133 of the semiconductor layer 130 may be about 1.3 kohm/square (kΩ/sq.) or less, and more specifically, the sheet resistance of the second region 132 and the third region 133 of the semiconductor layer 130 may be about 1 kohm/square (kΩ/sq.) or less.

The semiconductor layer of the thin film transistor according to the present embodiment may be formed by the spray coating method to have a crystal having an axis of C Axis Aligned Crystal (CAAC) having X-ray diffraction (XRD) main peak Miller index (hkl) value corresponding to (009) without a separate annealing process, and the manufacturing process is not complicated, so that the performance of the transistor may be improved without increasing the manufacturing cost. In addition, the second region 132 and the third region 133 of the semiconductor layer 130 may be treated with fluorine plasma, and the sheet resistance of the second region 132 and the third region 133 of the semiconductor layer 130 may be about 2 kohm/square (kΩ/sq.) or less, and for example, the sheet resistance of the second region 132 and the third region 133 of the semiconductor layer 130 may be about 1.3 kohm/square (kΩ/sq.) or less, and more specifically, the sheet resistance of the second region 132 and the third region 133 of the semiconductor layer 130 may be about 1 kohm/square (kΩ/sq.) or less, so that the efficiency of the channel of the thin film transistor may be increased by reducing the resistance of the source region and the drain region and increasing the carrier concentration.

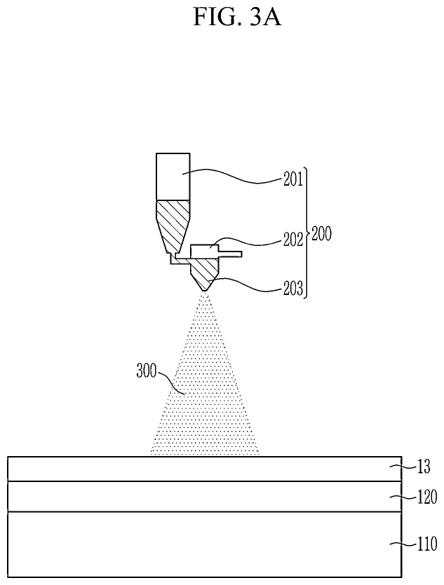

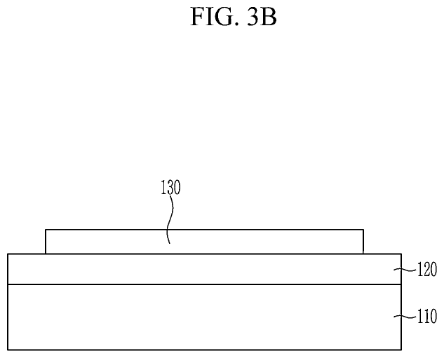

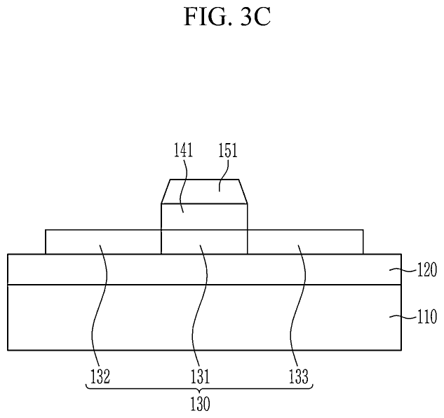

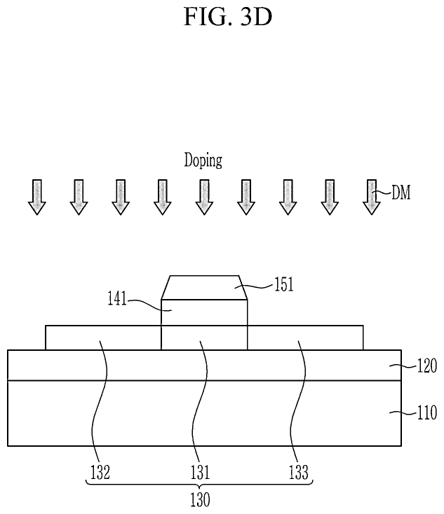

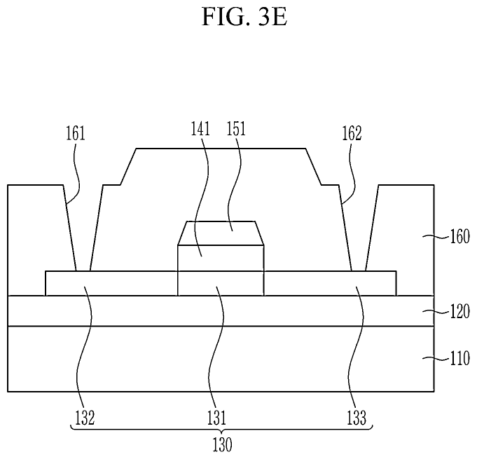

A method of manufacturing a thin film transistor according to an embodiment will be described with reference to FIGS. 3A to 3C together with FIG. 1. FIGS. 3A to 3E are cross-sectional views illustrating a method of manufacturing a thin film transistor according to an embodiment.

As shown in FIG. 3A, a buffer layer 120 is stacked on a substrate 110, and a semiconductor thin film 13 constituting the semiconductor layer 130 is stacked on the buffer layer 120.

The semiconductor thin film 13 may be formed by a spray coating method using a spray coating apparatus 200.

The spray coating apparatus 200 may include a solution supply unit 201 for receiving a spray solution, a gas supply unit 202, and a nozzle 203.

The operation of stacking the semiconductor thin film 13 may include preparing a process solution in which a stabilizer and a precursor of the metal included in the oxide semiconductor of the semiconductor layer 130 are mixed with a volatile solvent, spraying the process solution through the nozzle 203 together with the carrier gas supplied through the gas supply unit 202, and evaporating the volatile solvent contained in the second process solution. By repeating the process of forming the thin semiconductor thin film by spraying and evaporating the process solution as described above several times, the semiconductor thin film 13 may be stacked.

The semiconductor layer 130 may include at least one of Indium-Gallium-Zinc Oxide (IGZO), Indium-Zinc-Tin Oxide (IZTO), Indium-Gallium-Zinc-Tin Oxide (IGZTO), and Indium-Gallium Oxide (IGO), and for example, the indium (In) precursor may include indium (III) chloride (InCl₃), the gallium (Ga) precursor may include gallium(III) nitrate hydrate (Ga(NO₃)₃·xH₂O), the zinc (Zn) precursor may include zinc acetate dehydrate (Zn(CH₃COO)₂·2H₂O), and the tin (Sn) precursor may include tin(II) chloride dihydrate (SnCl₂·2H₂O).

The stabilizer may include ammonium acetate (CH₃CO₂NH₄) (AA), and the solvent may include 2-methoxyethanol (CH₃OCH₂CH₂OH).

The stacking of the semiconductor thin film 13 may be performed under a process temperature of about 350° C. to about 450° C.

As the spray coating process is repeated, the thickness of the semiconductor thin film 13 may be increased, and the crystal size of the semiconductor thin film 13 may be increased.

The semiconductor thin film 13 may have a crystal of a C Axis Aligned Crystal (CAAC) having an X-ray diffraction (XRD) main peak Miller index (hkl) value corresponding to (009).

In order to stack the semiconductor layer 130, when the spray coating process is repeated, the crystals may be aligned in a row from the bottom to the top along the thickness direction of the semiconductor layer 130 while the thin semiconductor layer is stacked several times.

When the spray coating process is performed, a crystal nucleus is formed in the semiconductor layer at the beginning of the process, and the crystal is grown around the crystal nucleus as an additional semiconductor layer is stacked on the crystal nucleus by a spray coating process, so that the semiconductor layer is crystalized, and by repeating this process, the central axes of the crystals may be aligned in a row from the bottom surface to the top surface of the semiconductor layer 130.

The semiconductor layer 130 as shown in FIG. 3B is formed by stacking the semiconductor thin film 13 by the spray coating manner and forming a crystallized oxide semiconductor layer and then patterning the oxide semiconductor layer.

As shown in FIG. 3C, the gate insulating film 141 and the gate electrode 151 may be formed to overlap the first region of the semiconductor layer 130.

The gate insulating film 141 and the gate electrode 151 may be formed by sequentially stacking a gate insulating film layer and a gate electrode layer on the semiconductor layer 130 and then patterning the gate insulating film layer and the gate electrode layer.

As shown in FIG. 3D, the semiconductor layer 130 may be plasma-treated by using process gas DM by using the gate insulating film 141 and the gate electrode 151 as a mask, and impurities may be doped into the second region 132 and the third region 133 of the semiconductor layer 130 through the plasma treatment.

For example, the process gas DM may include fluorine, and more specifically, nitrogen trifluoride. Through this, the second region 132 and the third region 133 of the semiconductor layer 130 may be doped with fluorine.

After the second region 132 and the third region 133 are plasma treated, the passivation layer 160 is stacked and a first contact hole 161 and a second contact hole 162 are formed in a passivation layer 160, and then the source electrode 171 connected to the second region 132 of the semiconductor layer 130 through the first contact hole 161 and the drain electrode 172 connected to the third region 133 of the semiconductor layer 130 through the second contact hole 162 are formed as shown in FIG. 3E to form the thin film transistor as illustrated in FIG. 1.

According to the method of manufacturing the thin film transistor according to the present embodiment, by repeating the process of spraying the solution in which the precursor and the stabilizer of the material included in the oxide semiconductor is mixed with a volatile solvent together with carrier gas, such as nitrogen, and evaporating the volatile solvent and forming the thin semiconductor thin film at a temperature of about 350° C. to about 450° C. several times, the crystallized oxide semiconductor layer 130 including a crystal of a C Axis Aligned Crystal (CAAC) having the XRD (X-ray diffraction) main peak Miller index (hkl) value corresponding to (009), in which the crystal axes are aligned in a row in the thickness direction may be formed.

In addition, impurities, for example, fluorine, are doped to the second region 132 and the third region 133 of the semiconductor layer 130 by performing the plasma treatment by using the gate insulating film 141 and the gate electrode 151 as a mask, thereby reducing the resistance and increasing the carrier concentration, and thus increasing the efficiency of the channel of the thin film transistor.

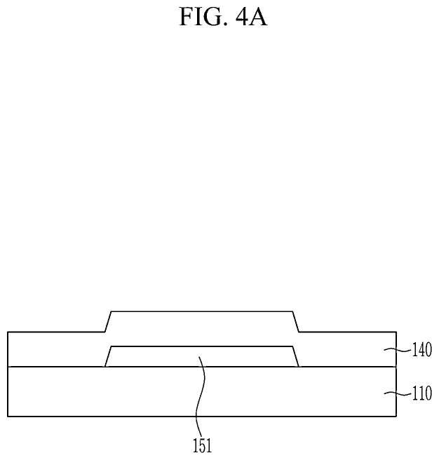

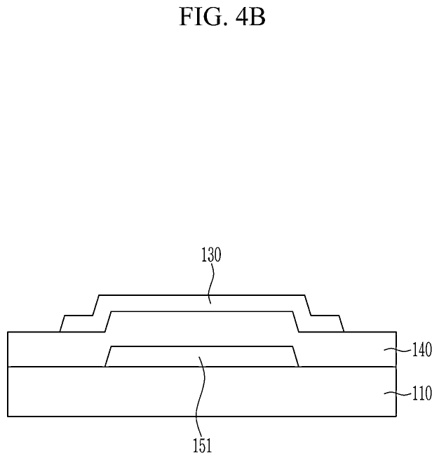

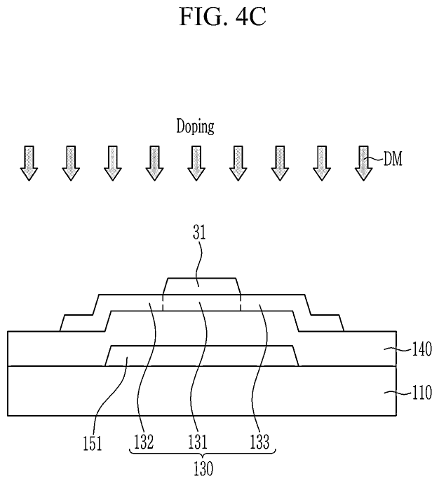

A method of manufacturing a thin film transistor according to another embodiment will be described with reference to FIGS. 4A to 4C together with FIG. 2. FIGS. 4A to 4C are cross-sectional views illustrating a method of manufacturing a thin film transistor according to another embodiment.

As shown in FIG. 4A, a gate electrode 151 is formed on a substrate 110, and a gate insulating film 140 is formed on the gate electrode 151.

As shown in FIG. 4B, the semiconductor layer 130 is formed on the gate insulating film 140 by a spray coating method under a process temperature of about 350° C. to about 450° C.

The semiconductor layer 130 may have a C Axis Aligned Crystal (CAAC) crystal having an X-ray diffraction (XRD) main peak and a Miller index hkl value corresponding to (009).

As shown in FIG. 4C, a blocking layer 31 may be formed on the semiconductor layer 130, the semiconductor layer 130 may be plasma-treated by using process gas DM by using the blocking layer 31 as a mask, and impurities may be doped into a second region 132 and a third region 133 of the semiconductor layer 130 through the plasma treatment.

For example, the process gas DM may include fluorine, and more specifically, nitrogen trifluoride. Through this, the second region 132 and the third region 133 of the semiconductor layer 130 may be doped with fluorine.

After the second region 132 and the third region 133 are plasma treated, a source electrode 171 and a drain electrode 172 are formed on the second region 132 and the third region 133 of the semiconductor layer 130 to form a thin film transistor as shown in FIG. 2.

Then, experimental examples will be described.

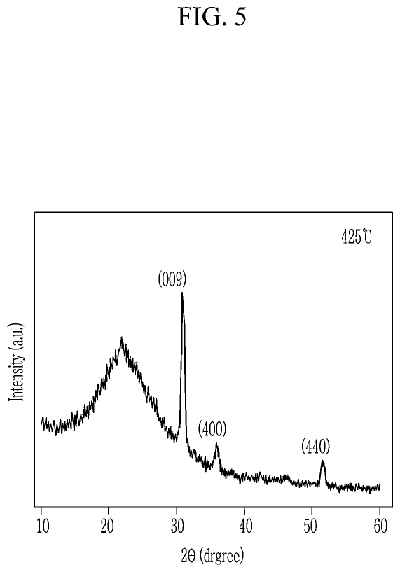

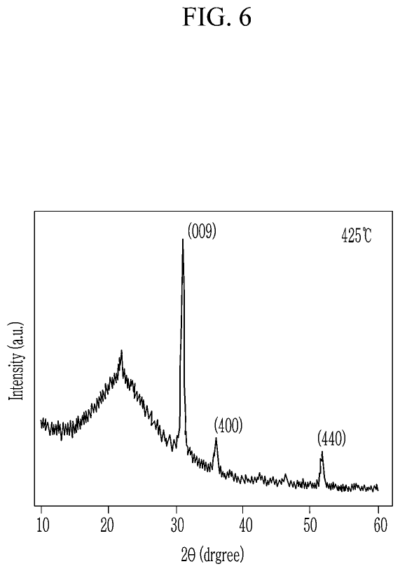

First, a first experimental example will be described with reference to FIGS. 5 and 6. FIGS. 5 and 6 are graphs illustrating the results of one experimental example. In the first experimental example, after forming an oxide semiconductor layer of IGZO under a process temperature of about 425° C. and about 450° C. by a spray coating method, XRD (X-ray diffraction) results are shown in FIGS. 5 and 6.

Referring to FIGS. 5 and 6, it could be seen that when IGZO that is the oxide semiconductor layer is stacked by a spray coating method, like the method of manufacturing the thin film transistor according to the embodiment, as a result of X-ray diffraction (XRD), the crystal of IGZO has a main peak value at a 2theta (2θ) value of about 31.09°, and has the C Axis Aligned Crystal (CAAC) having the main peak Miller index (hkl) value of (009).

As such, as described with reference to the first experimental example and the second experimental example, it could be seen that when the oxide semiconductor layer of IGZO is formed under a process temperature of about 400° C. or more by a spray coating method, a crystallized oxide semiconductor layer 130 including a crystal of C Axis Aligned Crystal (CAAC) having an X-ray diffraction (XRD) main peak Miller index (hkl) value corresponding to (009) could be formed.

Then, with reference to Table 1, the second experimental example will be described. In the second experimental example, after the semiconductor layer including IGZO was formed with a thickness of about 25 nm by using a sputtering method, the semiconductor layer was plasma-treated by using process gas in which the ratios of argon (Ar) and oxygen (O₂) are the same under conditions: power of about 200 W, a flow rate of about 30 sccm (Ar flow), a process temperature of about 200 degrees (° C.), and a pressure of about 1.0 Torr, and then sheet resistance was measured, and the results are represented in Table 1.

Table

Referring to Table 1, it can be seen that by plasma-treating the oxide semiconductor layer formed by the sputtering method by using argon (Ar) gas, as the plasma treatment time may be increased, the sheet resistance of the semiconductor layer may decrease, and the sheet resistance of the semiconductor layer is reduced to about 2.7 Kohm/square.

TABLE 1

| Time (s) | Sheet Resistance (kΩ/sq) |
|---|---|
| 80 | 42.48 |
| 100 | 31.99 |
| 140 | 23.83 |
| 160 | 5.20 |
| 180 | 2.91 |
| 200 | 3.79 |
| 300 | 2.72 |
| 600 | 8.25 |

Next, with reference to Tables 2 and 3, a third experimental example will be described. In the third experimental example, after the semiconductor layer including IGZO was formed to have a thickness of about 25 nm by using the sputtering method, the semiconductor layer was plasma-treated by using nitrogen trifluoride under power of about 200 W, and then sheet resistance was measured, and the results are represented in Tables 2 and 3. Referring to Table 2 and Table 3, it can be seen that by plasma-treating the oxide semiconductor layer formed by the sputtering method by using nitrogen trifluoride (NF₃) gas, as the plasma treatment time is increased, the sheet resistance of the semiconductor layer may decrease, and the sheet resistance of the semiconductor layer is reduced to about 2.7 Kohm/square.

TABLE 2

| | Sheet Resistance (kΩ/sq.) | | | |
|---|---|---|---|---|
| Time (S) | Average | Source/drain | Edge | Center |
| 40 | 5.14 | 0.45 | 5.73 | 4.49 |
| 60 | 3.81 | 0.24 | 3.95 | 3.66 |
| 80 | 3.41 | 0.16 | 3.04 | 3.49 |
| 100 | 3.47 | 0.34 | 4.24 | 2.87 |
| 110 | 3.07 | 0.3 | 3.48 | 2.77 |
| 120 | 3.18 | 0.24 | 3.70 | 3.01 |
| 130 | 3.67 | 0.79 | 6.23 | 3.05 |

TABLE 3

| | NH₃ Time (s) | | | |
|---|---|---|---|---|
| Sheet Resistance (kΩ/sq.) | 160 | 200 | 240 | 280 |
| Average | 336 | 21.52 | 12.09 | 2.77 |
| Source/drain | 626 | 22.17 | 9.95 | 0.68 |
| Maximum | 2221 | 93.8 | 41.2 | 4.39 |
| Minimum | 29 | 5.5 | 3.7 | 1.93 |

Next, with reference to Table 4, a fourth experimental example will be described. In the fourth experimental example, the semiconductor layer of IGZO was formed to have various thicknesses by using the spray coating method under a deposition temperature of about 375° C., and the sheet resistance was measured while varying the time of the plasma treatment using nitrogen trifluoride (NF₃), and the results are represented in Table 4. Referring to Table 4, it can be seen that when IGZO is formed by the spray coating method under the deposition temperature of about 375° C. and plasma-treated by using nitrogen trifluoride (NF₃), the sheet resistance of the semiconductor layer is reduced, and the sheet resistance of the semiconductor layer is reduced to about 1.3 Kohm/square.

TABLE 4

| | Sheet Resistance (kΩ/sq.) | | | |
|---|---|---|---|---|
| Time\thickness | 4 nm | 8 nm | 12 nm | 16 nm |
| 140 s | 16.43 | 3.444 | 4.116 | 1.845 |
| 180 s | 5.694 | 4.019 | 1.955 | 1.850 |
| 220 s | 4.328 | 2.832 | 1.683 | 1.353 |
| 240 s | 3.567 | 2.024 | 3.676 | 1.252 |
| 260 s | 12.82 | 2.198 | 2.156 | 1.485 |

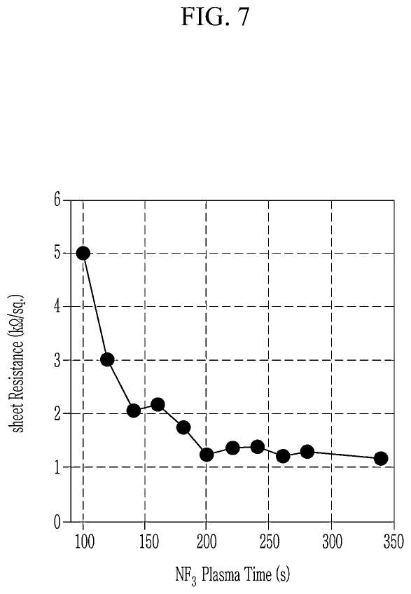

Next, a fifth experimental example will be described with reference to FIG. 7. FIG. 7 is a graph illustrating the results of one experimental example. In the fifth experimental example, the semiconductor layer of IGZO was formed to have a thickness of about 50 nm by using the spray coating method under a deposition temperature of about 400° C., and the sheet resistance was measured while varying the time of the plasma treatment using nitrogen trifluoride (NF₃), and the results are represented in Table 7. Referring to Table 7, it can be seen that when IGZO is formed by the spray coating method under the deposition temperature of about 400° C. and plasma-treated by using nitrogen trifluoride (NF 3), the sheet resistance of the semiconductor layer is reduced, and the sheet resistance of the semiconductor layer is reduced to about 1.0 Kohm/square.

Next, a sixth experimental example will be described with reference to Table 5. In the sixth experimental example, after a buffer layer containing zirconium (Zr) aluminum (Al) oxide (ZrAlOx) was formed under the semiconductor layer, a semiconductor layer of IGZO was formed by a spray coating method, and plasma-treated by using nitrogen trifluoride (NF₃), and then sheet resistance was measured, and the results are represented in Table 5.

Referring to Table 5, it can be seen that when the buffer layer containing zirconium (Zr) aluminum (Al) oxide (ZrAlOx) is formed, and then a semiconductor layer of IGZO is formed by the spray coating method and plasma treated by using nitrogen trifluoride (NF₃), the sheet resistance of the semiconductor layer is reduced to about 0.3 Kohm/square.

TABLE 5

| Thickness(nm) | 12 | 12 | 8 | 8 | 12 |
|---|---|---|---|---|---|
| Sheet Resistance | 0.244 | 0.706 | 1.008 | 1.033 | 0.495 |
| (kΩ/sq.) | | | | | |

Further, a seventh experimental example will be described. In the seventh experimental example, in the case where a semiconductor layer of IGZO was formed to have a thickness of about 30 nm by the sputtering method, and the semiconductor layer was crystalized for about 1 hour at a temperature of about 400° C., and then plasma-treated by using nitrogen trifluoride (NF₃) for about 70 seconds, the sheet resistance of the semiconductor layer decreased to about 0.4 Kohm/square. Referring to the results of the Second to Seventh Experimental Examples, it can be seen that like the thin film transistor and the method of manufacturing the same according to the embodiment, in the case where IGZO, which is the oxide semiconductor layer, is laminated by the spray coating method, and plasma-treated by using nitrogen trifluoride, the sheet resistance value is significantly reduced compared to the case where the semiconductor layer is formed by the sputtering method and doped with impurities, and it can be seen that the value of the sheet resistance of the semiconductor layer is reduced to a similar extent to the case where the semiconductor layer is formed by the sputtering method and crystallized through a separate process.

As such, according to the thin film transistor and the method of manufacturing the same according to the embodiment, it can be seen that by doping impurities in the source region and the drain region through plasma treatment after laminating the semiconductor layer by the spray coating method, the sheet resistance may be equal to or less than about 2 kohm/square (kΩ/sq.), and for example, the sheet resistance of the second region 132 and the third region 133 of the semiconductor layer 130 may be equal to or less than about 1.3 kohm/square (kΩ/sq.), and more specifically, the sheet resistance of the second region 132 and the third region 133 of the semiconductor layer 130 may be equal to or less than about 1 kohm/square (kΩ/sq.).

Although the embodiment has been described, this disclosure is not limited thereto, and it is possible to carry out various modifications within the scope of the claims, the detailed description of the embodiments, and the accompanying drawings, and the modifications belong to the scope of the this disclosure as a matter of course.

### DESCRIPTION OF SYMBOLS

110: Substrate
120: Buffer layer
130: Semiconductor layer
141: Gate insulating film
151: Gate electrode
160: Passivation layer
161, 162: Contact hole
171: Source electrode
172: Drain electrode

What is claimed is:

1. A thin film transistor, comprising:
a gate electrode disposed on a substrate;
a semiconductor layer including a channel region overlapping the gate electrode with a gate insulating film interposed therebetween, and a source region and a drain region disposed on both sides of the channel region; and
a source electrode and a drain electrode which are in contact with the source region and the drain region of the semiconductor layer,
wherein the semiconductor layer includes a crystallized oxide semiconductor,
the crystallized oxide semiconductor includes a crystal having an X-ray diffraction (XRD) main peak Miller index (hkl) value of (009), and
the source region and the drain region are doped with fluorine.

2. The thin film transistor of claim 1, wherein:
the source region includes a first offset region between a region overlapping the source electrode and the channel region,
the drain region includes a second offset region between a region overlapping the drain electrode and the channel region, and
the first offset region and the second offset region are doped with fluorine.

3. The thin film transistor of claim 1, wherein:
the crystal of the crystallized oxide semiconductor includes a C Axis Aligned Crystal (CAAC).

4. The thin film transistor of claim 1, wherein:
the semiconductor layer includes indium.

5. The thin film transistor of claim 4, wherein:
the semiconductor layer includes at least one of Indium-Gallium-Zinc Oxide (IGZO), Indium-Zinc-Tin Oxide (IZTO), Indium-Gallium-Zinc-Tin Oxide (IGZTO), Indium-Gallium Oxide (IGO), and Indium-Gallium-Tin Oxide (IGTO).

6. The thin film transistor of claim 1, wherein:
the source region and the drain region are plasma-treated with nitrogen trifluoride.

7. The thin film transistor of claim 1, wherein:
sheet resistance of the source region and the drain region is about 2 kohm/square (kΩ/sq.) or less.

8. The thin film transistor of claim 7, wherein:
sheet resistance of the source region and the drain region is about 1.3 kohm/square (kΩ/sq.) or less.

9. The thin film transistor of claim 8, wherein:
sheet resistance of the source region and the drain region is about 1 kohm/square (kΩ/sq.) or less.

10. The thin film transistor of claim 1, wherein:
the semiconductor layer is formed at a process temperature of about 350 degrees (° C.) to about 450 degrees (° C.).

11. A method of manufacturing a thin film transistor, the method comprising:
forming a gate electrode on a substrate;
forming a semiconductor layer including a channel region overlapping the gate electrode with a gate insulating film interposed therebetween, and a source region and a drain region disposed on both sides of the channel region;
plasma-treating the source region and the drain region of the semiconductor layer by using gas containing fluorine, and
forming a source electrode and a drain electrode which are in contact with the semiconductor layer,
wherein the forming of the semiconductor layer includes spray coating a solution containing a volatile solvent, a metal precursor, and a stabilizer on the substrate.

12. The method of claim 11, wherein:
the forming of the semiconductor layer is performed at a process temperature of about 350 degrees (° C.) to about 450 degrees (° C.).

13. The method of claim 12, wherein:
the forming of the semiconductor layer is performed at a process temperature of about 400 degrees (° C.) to about 450 degrees (° C.).

14. The method of claim 11, wherein:
the plasma-treating is plasma treatment using nitrogen trifluoride.

15. The method of claim 11, wherein:
the plasma-treating includes plasma-treating the semiconductor layer by using the gate electrode disposed on the channel region as a mask.

16. The method of claim 11, wherein:
the spray coating includes:
preparing the solution by mixing the metal precursor and the stabilizer with the volatile solvent;
spraying the solution together with carrier gas onto the substrate, and
evaporating the volatile solvent of the solution.

17. The method of claim 16, wherein:
the spray coating is performed at a process temperature of about 350 degrees (° C.) to about 450 degrees (° C.).

18. The method of claim 17, wherein:
the spray coating is performed at a process temperature of about 400 degrees (° C.) to about 450 degrees (° C.).

19. The method of claim 16, wherein:
the forming of the semiconductor layer includes repeating the spray coating several times.

20. The method of claim 11, wherein:
the metal precursor includes indium, and
the semiconductor layer includes at least one of Indium-Gallium-Zinc Oxide (IGZO), Indium-Zinc-Tin Oxide (IZTO), Indium-Gallium-Zinc-Tin Oxide (IGZTO), Indium-Gallium Oxide (IGO), and Indium-Gallium-Tin Oxide (IGTO).
